(19) United States
(12) Patent Application Publication
(10) Pub. No.: US 2015/0189791 A1
(43) Pub. Date: Jul. 2, 2015

(54) RADIATOR FOR LIQUID-COOLED-TYPE COOLING DEVICE AND METHOD OF MANUFACTURING THE SAME

(71) Applicant: SHOWA DENKO K.K., Tokyo (JP)

(72) Inventor: Shinobu TAMURA, Oyama-shi (JP)

(73) Assignee: SHOWA DENKO K.K., Tokyo (JP)

(21) Appl. No.: 14/583,199

(22) Filed: Dec. 26, 2014

(30) Foreign Application Priority Data
Dec. 26, 2013 (JP) 2013-268462

(51) Int. Cl. H05K 7/20; B23P 15/26; F28D 1/04

(52) U.S. Cl. CPC H05K 7/20218; F28D 1/04; B23P 15/26

(57) ABSTRACT

A radiator for a liquid-cooled-type cooling device includes a plurality of elongated rectangular fin plates and rod-shaped connection members. The fin plates are disposed, while being separated from one another in the thickness direction, such that their width direction coincides with the vertical direction. The connection members extend in a direction intersecting with the longitudinal direction of the fin plate, and connect and unite all the fin plates together. A first cutout is formed in an upper side edge portion of each fin plate, and a second cutout is formed in a lower side edge portion thereof at a position shifted from the first cutout in the longitudinal direction of the fin plate. The connection members are press-fitted into the first and second cutouts such that they do not project from the cutouts, whereby all the fin plates are connected and united together by the connection members.

### BACKGROUND OF THE INVENTION

The present invention relates to a radiator used for a liquid-cooled-type cooling device which cools a heat generation body which is composed of, for example, an electronic component such as a semiconductor device, and to a method of manufacturing such a radiator.

In the following description and claims, the upper and lower sides of FIG. 2 will be referred to as “upper” and “lower,” respectively.

For example, a liquid-cooled-type cooling device disclosed in Japanese Patent Application Laid-Open (kokai) No. 2012-37136 has been proposed as a liquid-cooled-type cooling device for cooling a power device (semiconductor device), such as an IGBT (Insulated Gate Bipolar Transistor), which is used for a power conversion apparatus mounted on an electric vehicle, a hybrid vehicle, an electric rail car, or the like.

The liquid-cooled-type cooling device disclosed in the above-described publication includes a casing having a top wall, a bottom wall, and a peripheral wall. A cooling liquid flow channel through which a cooling liquid flows, an inlet header section which is located upstream of the cooling liquid flow channel and into which the cooling liquid flows, and an outlet header section which is located downstream of the cooling liquid flow channel and from which the cooling liquid flows out are provided within the casing. A radiator is disposed in the cooling liquid flow channel within the casing. Heat generated from a heat generation body(s) attached to at least one of the outer surface of the top wall of the casing and the outer surface of the bottom wall of the casing is radiated or transferred by the radiator to the cooling liquid flowing through the cooling liquid flow channel. The radiator is composed of a plurality of elongated rectangular fin plates. The fin plates are disposed parallel to one another such that they are spaced from one another, and the upper and lower side edge portions of the fin plates are brazed to the top wall and the bottom wall of the casing. A plurality of projections are interspersed on each of opposite faces of each of the fin plates, excluding those at opposite ends. The fin plates are brazed together in a state in which the projections of each fin plate are in contact with the corresponding projections of fin plates adjacent thereto.

The liquid-cooled-type cooling device disclosed in the above-described publication is manufactured by a method including the following steps. A plurality of fin plates are stacked such that the projections of each fin plate come into contact with the corresponding projections of fin plates adjacent thereto. The stacked fin plates are disposed between upper and lower main body plates which constitute the casing. Periphery portions of the two main body plates are brazed together, the two main body plates and the upper and lower side edge portions of the fin plates are brazed together, and the projects of adjacent fin plates are brazed together, whereby the liquid-cooled-type cooling device is completed.

However, the radiator of the liquid-cooled-type cooling device disclosed in the above-described publication has the following problem. Before the two main body plates and the fin plates are brazed together and the projects of adjacent fin plates are brazed together, all the fin plates are separate and may cause positional shifts. Therefore, when the liquid-cooled-type cooling device is manufactured, handling of the fin plates becomes troublesome, and work for manufacturing the liquid-cooled-type cooling device becomes difficult.

### SUMMARY OF THE INVENTION

An object of the present invention is to solve the above-described problem and to provide a radiator for a liquid-cooled-type cooling device which facilities handling of all fin plates at the time of manufacture of a liquid-cooled-type cooling device. Another object of the present invention is to provide a method of manufacturing such a radiator.

To fulfill the above object, the present invention comprises the following modes.

1) A radiator for a liquid-cooled-type cooling device which includes a casing having a top wall, a bottom wall, and a peripheral wall, the cooling device having a cooling liquid flow channel which is provided in the casing and through which a cooling liquid having flowed into the casing flows, the cooling device being adapted to cool a heat generation body attached to at least one of an outer surface of the top wall of the casing and an outer surface of the bottom wall thereof by the cooling liquid flowing through the cooling liquid flow channel, the radiator being disposed in the cooling liquid flow channel within the casing and radiating heat generated from the heat generation body to the cooling liquid, the radiator comprising:

a plurality of elongated rectangular fin plates disposed in parallel such that the fin plates are spaced from one another; and

rod-shaped first and second connection members which extend in a direction intersecting with a longitudinal direction of the fin plates and which connect and unite all the fin plates together, wherein

all the fin plates are disposed, while being spaced from one another in a thickness direction of the fin plates, such that the longitudinal direction of the fin plates coincides with a flow direction of the cooling liquid, and a width direction of the fin plates coincides with a vertical direction;

the first connection member is fixed to one of side edge portions of each fin plate located on opposite sides in the width direction, and the second connection member is fixed to the other of the side edge portions of the fin plate;

a first cutout into which the first connection member is press-fitted is formed in the one side edge portion of each fin plate, and a second cutout into which the second connection member is press-fitted is formed in the other side edge portion of the fin plate at a position shifted from the first cutout in the longitudinal direction of the fin plate; and

the first connection member is press-fitted into the first cutout such that the first connection member does not project from the first cutout, and the second connection member is press-fitted into the second cutout such that the second connection member does not project from the second cutout, whereby all the fin plates are connected and united together by the first and second connection members.

2) A radiator for a liquid-cooled-type cooling device according to par. 1), wherein each fin plate has a wavy sectional shape when the fin plate is cut along a plane orthogonal to the width direction thereof and has crest portions and trough portions formed alternatingly, and the cooling liquid flows between two adjacent fin plates while meandering.

3) A radiator for a liquid-cooled-type cooling device according to par. 1), wherein the first cutout is formed in the one side edge portion of each fin plate at a position near a first end in the longitudinal direction, the second cutout is formed in the other side edge portion of the fin plate at a position near a second end in the longitudinal direction, a third cutout is formed in the one side edge portion of the fin plate at a position near the second end in the longitudinal direction, and a fourth cutout is formed in the other side edge portion of the fin plate at a position near the first end in the longitudinal direction.

4) A radiator for a liquid-cooled-type cooling device according to par. 3), wherein

an inter-plate spacing which is a spacing between adjacent fin plates is the same among all the fin plates;

a rod-shaped resistance imparting member is disposed at a position near the second ends of the fin plates in the longitudinal direction such that the resistance imparting member extends through a plurality of fin plates which are a portion of all the fin plates and are located on one side in a direction of arrangement of the fin plates; and

the resistance imparting member is fitted into the third cutout of each fin plate which is formed in the one side edge portion thereof at a position near the second end.

5) A radiator for a liquid-cooled-type cooling device according to par. 1), wherein an inter-plate spacing which is a spacing between adjacent fin plates is narrow on one side in a direction of arrangement of the fin plates, and is wide on the other side in the direction of arrangement.

6) A radiator for a liquid-cooled-type cooling device according to par. 5), wherein the inter-plate spacing which is the spacing between adjacent fin plates gradually increases from one side toward the other side in the direction of arrangement of the fin plates.

7) A liquid-cooled-type cooling device comprising:

a casing having a top wall, a bottom wall, and a peripheral wall;

a cooling liquid flow channel which is provided in the casing and through which a cooling liquid flows;

an inlet header section which is provided in the casing to be located upstream of the cooling liquid flow channel and into which the cooling liquid flows;

an outlet header section which is provided in the casing to be located downstream of the cooling liquid flow channel and from which the cooling liquid flows out; and

a radiator which is disposed in the cooling liquid flow channel within the casing and which radiates heat to the cooling liquid flowing through the cooling liquid flow channel, the heat being generated from a heat generation body attached to at least one of an outer surface of the top wall of the casing and an outer surface of the bottom wall of the casing, wherein

the radiator for a liquid-cooled-type cooling device according to par. 1) is disposed such that the longitudinal direction of the fin plates coincides with a direction along which the inlet header section and the outlet header section are provided and the width direction of the fin plates coincides with the vertical direction; and

upper side edge portions of all the fin plates are joined to the top wall of the casing, and lower side edge portions of all the fin plates are joined to the bottom wall of the casing.

8) A liquid-cooled-type cooling device according to par. 7), wherein each fin plate of the radiator has a wavy sectional shape when the fin plate is cut along a plane orthogonal to the width direction thereof and has crest portions and trough portions formed alternatingly, and the cooling liquid flows between two adjacent fin plates while meandering.

9) A liquid-cooled-type cooling device according to par. 7), wherein the first cutout is formed in the one side edge portion of each fin plate of the radiator at a position near a first end in the longitudinal direction, the second cutout is formed in the other side edge portion of the fin plate at a position near a second end in the longitudinal direction, a third cutout is formed in the one side edge portion of the fin plate at a position near the second end in the longitudinal direction, and a fourth cutout is formed in the other side edge portion of the fin plate at a position near the first end in the longitudinal direction.

10) A liquid-cooled-type cooling device according to par. 9), wherein

the inlet header section and the outlet header section of the casing are elongated in a direction orthogonal to a flow direction of the cooling liquid in the cooling liquid flow channel,

a cooling liquid inlet is provided at one end of the inlet header section, and a cooling liquid outlet is provided at one end of the outlet header section which is located on the same side as the one end of the inlet header section;

an inter-plate spacing which is a spacing between adjacent fin plates of the radiator is the same among all the fin plates;

a rod-shaped resistance imparting member is disposed at a position near the second ends of the fin plates in the longitudinal direction such that the resistance imparting member extends through a plurality of fin plates which are a portion of all the fin plates and are located on one side in a direction of arrangement of the fin plates;

the resistance imparting member is fitted into the third cutout of each fin plate which is formed in the one side edge portion thereof at a position near the second end; and

the radiator is disposed such that the side of the radiator where the resistance imparting member is located on the side where the cooling liquid inlet and the cooling liquid outlet are provided.

11) A liquid-cooled-type cooling device according to par. 7), wherein

the inlet header section and the outlet header section of the radiator are elongated in a direction orthogonal to a flow direction of the cooling liquid in the cooling liquid flow channel,

a cooling liquid inlet is provided at one end of the inlet header section, and a cooling liquid outlet is provided at one end of the outlet header section which is located on the same side as the one end of the inlet header section;

an inter-plate spacing which is a spacing between adjacent fin plates of the radiator is narrow on one side in a direction of arrangement of the fin plates, and is wide on the other side in the direction of arrangement; and

the radiator is disposed such that the side of the radiator where the inter-plate spacing is narrow is located on the side where the cooling liquid inlet and the cooling liquid outlet are provided.

12) A liquid-cooled-type cooling device according to par. 7), wherein

the inlet header section and the outlet header section are elongated in a direction orthogonal to a flow direction of the cooling liquid in the cooling liquid flow channel,

a cooling liquid inlet is provided at one end of the inlet header section, and a cooling liquid outlet is provided at one end of the outlet header section which is located on the same side as the one end of the inlet header section;

an inter-plate spacing which is a spacing between adjacent fin plates of the radiator gradually increases from one side toward the other side in a direction of arrangement of the fin plates; and

the radiator is disposed such that the side of the radiator where the inter-plate spacing is narrow is located on the side where the cooling liquid inlet and the cooling liquid outlet are provided.

13) A method of manufacturing a radiator for a liquid-cooled-type cooling device which includes a casing having a top wall, a bottom wall, and a peripheral wall, the cooling device having a cooling liquid flow channel which is provided in the casing and through which a cooling liquid having flowed into the casing flows, the cooling device being adapted to cool a heat generation body attached to at least one of an outer surface of the top wall of the casing and an outer surface of the bottom wall thereof by the cooling liquid flowing through the cooling liquid flow channel, the radiator being disposed in the cooling liquid flow channel within the casing and radiating heat generated from the heat generation body into the cooling liquid, the radiator including a plurality of elongated rectangular fin plates disposed in parallel such that the fin plates are spaced from one another, and rod-shaped first and second connection members which extend in a direction intersecting with a longitudinal direction of the fin plates and which connect and unite all the fin plates together, wherein all the fin plates are disposed, while being spaced from one another in a thickness direction of the fin plates, such that the longitudinal direction of the fin plates coincides with a flow direction of the cooling liquid, and a width direction of the fin plates coincides with a vertical direction, the first connection member is fixed to one of side edge portions of each fin plate located on opposite sides in the width direction, and the second connection member is fixed to the other of the side edge portions of the fin plate, a first cutout into which the first connection member is press-fitted is formed on the one side edge portion of each fin plate at a position near a first end in the longitudinal direction of the fin plate, and a second cutout into which the second connection member is press-fitted is formed on the other side edge portion of the fin plate at a position near a second end in the longitudinal direction of the fin plate, and the first connection member is press-fitted into the first cutout such that the first connection member does not project from the first cutout, and the second connection member is press-fitted into the second cutout such that the second connection member does not project from the second cutout, whereby all the fin plates are connected and united together by the first and second connection members,

the method comprising:

a first step of performing press working on a metal material plate so as to punch out a plurality of elongated rectangular fin plates in a half-punched state such that a longitudinal direction of the fin plates coincides with a width direction of the metal material plate, a width direction of the fin plates coincides with a longitudinal direction of the metal material plate, and opposite longitudinal ends of the fin plates are connected to respective bridge portions through connection portions, each fin plate having the first cutout which is formed in one side edge portion of the fin plate located on one side in the width direction thereof to be located at a position near the first end in the longitudinal direction, the second cutout which is formed in the other side edge portion of the fin plate located on the other side in the width direction thereof to be located at a position near the second end in the longitudinal direction;

a second step of bending parts of the bridge portions, each part being located between adjacent fin plates, into a generally S-like shape, to thereby bring the width direction of all the fin plates into coincident with the vertical direction;

a third step of press-fitting the first connection member into the first cutouts of all the fin plates such that the first connection member does not project from the first cutouts and press-fitting the second connection member into the second cutouts of all the fin plates such that the second connection member does not project from the second cutouts; and

a fourth step of cutting all the connection portions which connect the fin plates to the bridge portions to thereby separate all the fin plates from the bridge portions.

14) A method of manufacturing a radiator for a liquid-cooled-type cooling device according to par. 13), wherein, in the first step, a portion of each fin plate between the first and second cutouts is deformed to have a wavy sectional shape when the fin plate is cut along a plane orthogonal to the width direction thereof.

15) A method of manufacturing a radiator for a liquid-cooled-type cooling device according to par. 13), wherein, in the first step, a third cutout is formed in the one side edge portion of the fin plate at a position near the second end in the longitudinal direction, and a fourth cutout is formed in the other side edge portion of the fin plate at a position near the first end in the longitudinal direction.

According to the radiator for a liquid-cooled-type cooling device of any one of pars. 1) through 6), a first cutout into which the first connection member is press-fitted is formed on one of side edge portions of each fin plate located on opposite sides in the width direction thereof, and a second cutout into which the second connection member is press-fitted is formed on the other of the side edge portions of the fin plate at a position shifted from the first cutout in the longitudinal direction of the fin plate; and the first connection member is press-fitted into the first cutout such that the first connection member does not project from the first cutout, and the second connection member is press-fitted into the second cutout such that the second connection member does not project from the second cutout, whereby all the fin plates are connected and united together by the first and second connection members. Therefore, all the fin plates can be firmly connected and united together. Accordingly, handling of all the fin plates at the time of manufacture of a liquid-cooled-type cooling device using the radiator of the above-described paragraphs 1) through 6) is facilitated, and the work of manufacturing the liquid-cooled-type cooling device becomes easy and simple.

Also, all the fin plates can have a thickness and a shape which are effective for enhancement of cooling performance.

According to the liquid-cooled-type cooling device of any one of pars. 7) through 9), at the time of manufacture of the liquid-cooled-type cooling device, handling of all the fin plates is facilitated because all the fin plates of the radiator are connected and united together by the connection members. Thus, the manufacturing work becomes simple.

According to the liquid-cooled-type cooling device of par. 8), the cooling liquid flows between two adjacent fin plates while meandering along the fin plates. Therefore, the area of a region of each fin plate which effectively works for heat transmission increases, and cooing performance can be enhanced.

According to the liquid-cooled-type cooling device of par. 10), it becomes difficult for the cooling liquid having flowed into the inlet header section to flow through a region of the cooling liquid flow channel on the side where the rod-shaped resistance imparting member is disposed, and it becomes easy for the cooling liquid to flow through a region of the cooling liquid flow channel on the opposite side. Accordingly, the distribution of flow rate in the direction of arrangement of the fin plates in the radiator can be made uniform, whereby a variation of cooling performance which is caused by a non-uniform distribution of flow rate can be restrained.

According to the liquid-cooled-type cooling device of par. 11) or 12), it becomes difficult for the cooling liquid having flowed into the inlet header section to flow through a region of the cooling liquid flow channel on the side where the spacing between adjacent fin plates is narrow, and it becomes easy for the cooling liquid to flow through a region of the cooling liquid flow channel on the opposite side where the spacing between adjacent fin plates is wide. Accordingly, the distribution of flow rate in the direction of arrangement of the fin plates in the radiator can be made uniform, whereby a variation of cooling performance which is caused by a non-uniform distribution of flow rate can be restrained.

According to the method of manufacturing a radiator for a liquid-cooled-type cooling device of any one of pars. 13) through 15), when the connection members are press-fitted into the cutouts of all the fin plates, all the fin plates have already been united by the bridge portions. Therefore, positional shift of the cutouts of all the fin plates can be prevented. Accordingly, the work of press-fitting the connection members into the cutouts of all the fin plates becomes easy, and the manufacturing work becomes simple. Also, it becomes possible to adjust the thickness and shape of all the fin plates such that the thickness and shape become effective for enhancement of cooling performance, and to set the spacing between adjacent fin plates to a proper spacing in consideration of the casing of the liquid-cooled-type cooling device to be used.

The method of manufacturing a radiator for a liquid-cooled-type cooling device of par. 15) is suitable for manufacture of the radiator of par. 4).

### BRIEF DESCRIPTION OF THE DRAWINGS

FIG. 1 is a perspective view showing the overall structure of a liquid-cooled-type cooling device in which a radiator for a liquid-cooled-type cooling device according to the present invention is used;

FIG. 2 is a sectional view taken along line A-A of FIG. 1;

FIG. 3 is a sectional view taken along line B-B of FIG. 2;

FIG. 4 is a partial perspective view showing first and second steps of a method of manufacturing a radiator used for the liquid-cooled-type cooling device shown in FIG. 1;

FIG. 5 is a partial enlarged view of FIG. 4;

FIG. 6 is a partial perspective view showing a third step of the method of manufacturing the radiator used for the liquid-cooled-type cooling device shown in FIG. 1;

FIG. 7 is a sectional view taken along line C-C of FIG. 5;

FIG. 8 is a partial perspective view showing a fourth step of the method of manufacturing the radiator used for the liquid-cooled-type cooling device shown in FIG. 1;

FIG. 9 is a perspective view showing another embodiment of the radiator for a liquid-cooled-type cooling device according to the present invention;

FIG. 10 is a horizontal sectional view showing a liquid-cooled-type cooling device in which the radiator shown in FIG. 9 is used; and

FIG. 11 is a horizontal sectional view showing still another embodiment of the radiator for a liquid-cooled-type cooling device according to the present invention and a liquid-cooled-type cooling device in which that radiator is used.

### DESCRIPTION OF THE PREFERRED EMBODIMENTS

Embodiments of the present invention will next be described with reference to the drawings.

The same members and portions are denoted by the same reference numerals throughout all the drawings.

In the present specification, the term “aluminum” encompasses aluminum alloys in addition to pure aluminum.

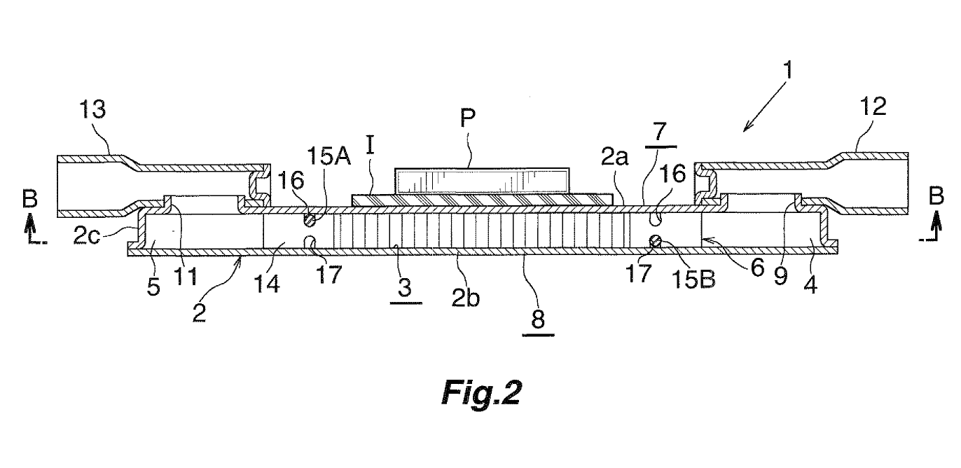

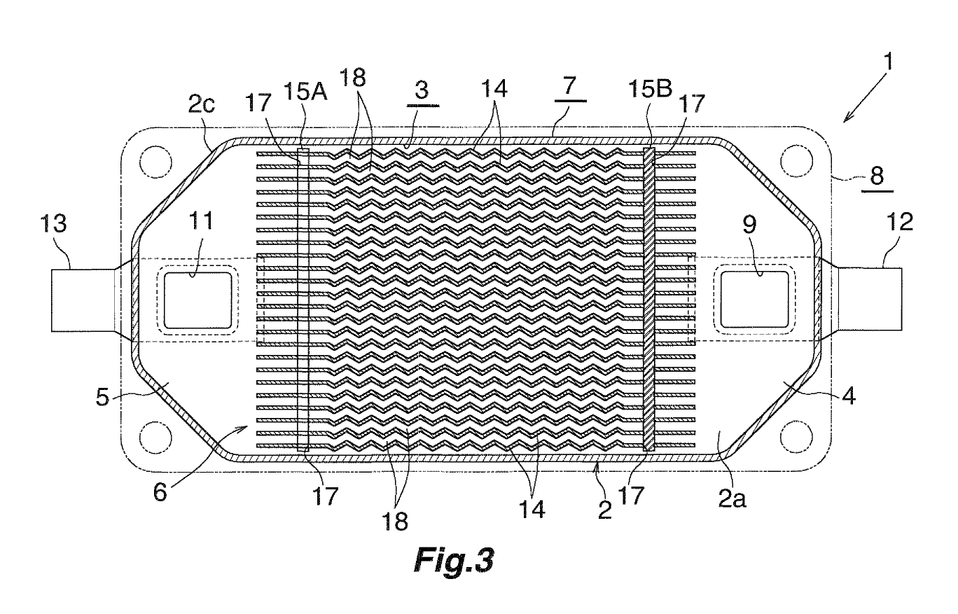

In the following description, the left-hand and right-hand sides of FIG. 2 will be referred to as “left” and “right,” respectively. The upper side of FIG. 3 will be refereed to as “front,” and the opposite side will be referred to as “rear.”

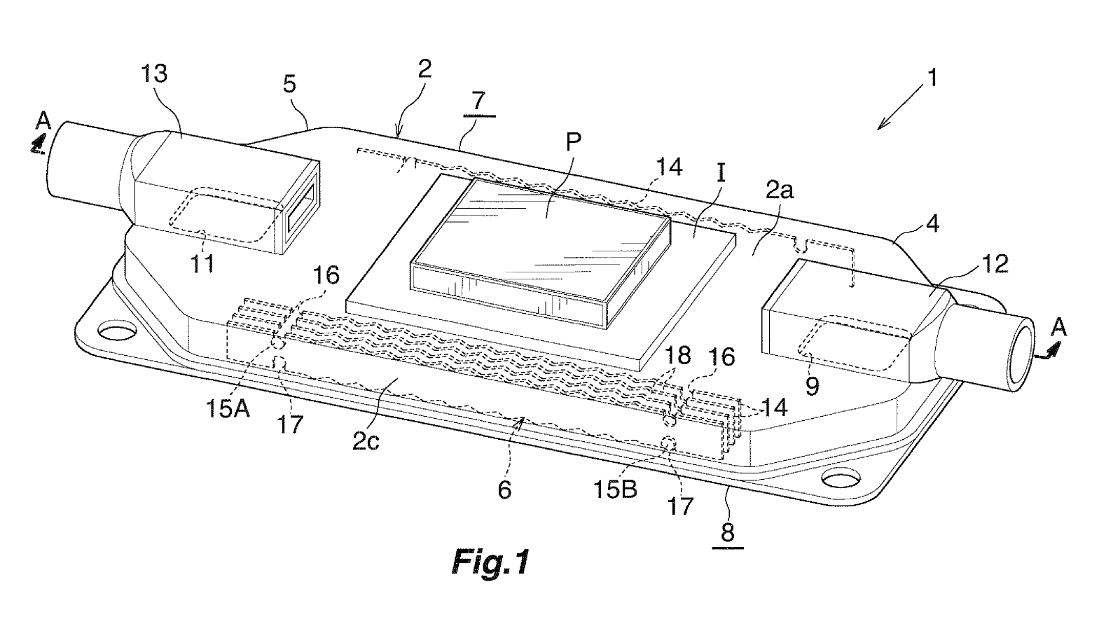

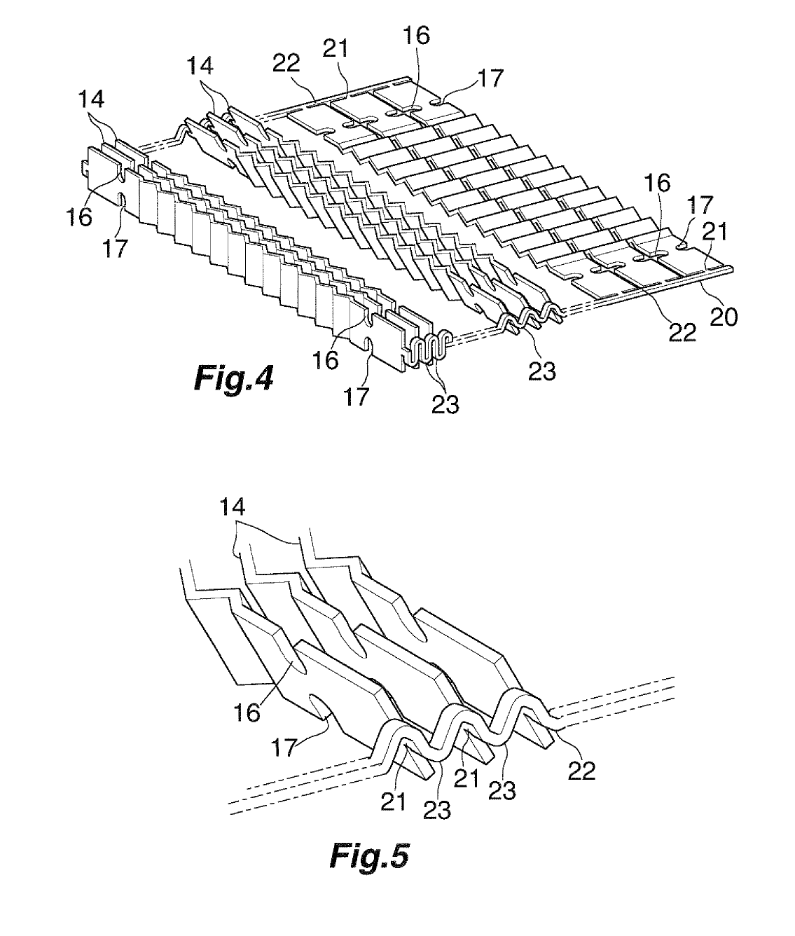

FIGS. 1 through 3 show a liquid-cooled-type cooling device in which a radiator for a liquid-cooled-type cooling device according to the present invention is used, and FIGS. 4 through 7 show a method of manufacturing the radiator for a liquid-cooled-type cooling device.

As shown in FIGS. 1 through 3, the liquid-cooled-type cooling device 1 includes a casing 2 having a top wall 2a, a bottom wall 2b, and a peripheral wall 2c. Within the casing 2, there are provided a cooling liquid flow channel 3 through which a cooling liquid flows from one side (right-hand side) to the other side (left-hand side) of the casing 2 in the longitudinal direction thereof, an inlet header section 4 which is located upstream (rightward) of the cooling liquid flow channel 3 and into which the cooling liquid flows, and an outlet header section 5 which is located downstream (leftward) of the cooling liquid flow channel 3 and from which the cooling liquid flows out. A radiator 6 is disposed in the cooling liquid flow channel 3 within the casing 2. Heat generated from a heat generation body P attached to at least one of the outer surface of the top wall 2a of the casing 2 and the outer surface of the bottom wall 2b thereof (attached to the outer surface of the top wall 2a in the illustrated example) is radiated or transferred by the radiator 6 to the cooling liquid flowing through the cooling liquid flow channel 3.

The casing 2 is formed by brazing a box-shaped upper constituent member 7 onto a plate-shaped lower constituent member 8. The upper constituent member 7 is formed of aluminum, is open downward, and constitutes the top wall 2a and the peripheral wall 2c. The lower constituent member 8 is formed of aluminum, and constitutes the bottom wall 2b. Each of the upper constituent member 7 and the lower constituent member 8 is formed from an aluminum brazing sheet having a brazing material layer formed on at least one surface of the sheet such that the brazing material layer is located inside the casing 2.

Each of the inlet header section 4 and the outlet header section 5 within the casing 2 extends in the width direction of the cooling liquid flow channel 3 (front-rear direction). A cooling liquid inlet 9 communicating with the inlet header section 4 is formed in the top wall 2a of the casing 2 at a position near one end (right end) of the top wall 2 to be located at the center in the front-rear direction. A cooling liquid outlet 11 communicating with the outlet header section 5 is formed in the top wall 2a of the casing 2 at a position near the other end (left end) of the top wall 2 to be located at the center in the front-rear direction. Also, an aluminum inlet pipe 12 and an aluminum outlet pipe 13 are brazed to the top wall 2a of the casing 2. The inlet pipe 12 is used to supply the cooling liquid into the inlet header section 4 through the cooling liquid inlet 7. The outlet pipe 13 is used to discharge the cooling liquid from the outlet header section 5 through the cooling liquid outlet 11.

The heat generation body P is a power device such as an IGBT, an IGBT module in which an IGBT is united with a control circuit and is accommodated in the same package, or an intelligent power module in which the IGBT module is united with a protection circuit and is accommodated in the same package. The heat generation body P is attached to outer surface of the top wall 2a of the casing 2 via an insulating member I.

The radiator 6 is composed of a plurality of elongated rectangular fin plates 14 formed of alumina and two rod-shaped connection members 15A and 15B. The fin plates 14 are disposed parallel to one another such that they are spaced from one another, their longitudinal direction coincides with the flow direction (left-right direction) of the cooling liquid in the cooling liquid flow channel 3, and their width direction coincides with the vertical direction. The connection members 15A and 15B extend in a direction (front-rear direction) intersecting with the longitudinal direction of the fin plates 14, and connect and unite all the fin plates 14 together. A split flow channel 18 through which the cooling liquid flows is formed between two adjacent fin plates 14 of the radiator 6. Such a split flow channel 18 is formed between the fin plate 14 at one end and a front side portion of the peripheral wall 2c of the casing 2 and between the fin plate 14 at the other end and a rear side portion of the peripheral wall 2c.

Cutouts 16 and 17 are formed in the upper and lower side edge portions of all the fin plates 14, respectively, at positions near the opposite ends in the longitudinal direction. The upper and lower cutouts 16 and 17 formed in one-end-side portion (portion near one end) of each fin plate 14 are located at the same position in the longitudinal direction of the fin plate 14. The upper and lower cutouts 16 and 17 formed in the other-end-side portion (portion near the other end) of each fin plate 14 are located at the same position in the longitudinal direction of the fin plate 14.

One or first connection member 15A is press-fitted into the first cutouts 16 formed in the left-end-side portions (portions near the left end) of the upper side edge portions of all the fin plates 14 such that the first connection member 15A does not project from the first cutout 16. The other or second connection member 15B is press-fitted into the second cutouts 17 formed in the right-end-side portions (portions near the right end) of the lower side edge portions of all the fin plates 14 such that the second connection member 15B does not project from the second cutouts 17. As a result, all the fin plates 14 are connected and united together by the connection member 15A and 15B. Namely, one connection member 15A (15B) is press-fitted into a cutout 16 (17) which is formed in a side edge portion of each fin plate 14 opposite the side edge portion thereof having a cutout 17 (16) into which the other connection member 15B (15A) is fitted, the cutout 16 (17) being located at a position shifted in the longitudinal direction of the fin plate 14 from the cutout 17 (16) into which the other connection member 15B (15A) is fitted.

Notably, the cutouts 16 in the right-end-side portions of the upper side edge portions of all the fin plates 14 are third cutouts, and the cutouts 17 in the left-end-side portions of the lower side edge portions of all the fin plates 14 are fourth cutouts.

When a portion of each fin plate 14 between the two cutouts 16 and 17 is cut by a plane orthogonal to the width direction (horizontal plane), that portion has a wavy sectional shape; i.e., has crest portions and trough portions alternatingly formed. Therefore, the cooling liquid flows between two adjacent fin plates 14 while meandering. The upper side edge portions of all the fin plates 14 are brazed to the inner surface of a portion of the upper constituent member 7 of the casing 2, which portion forms the top wall 2a. The lower side edge portions of all the fin plates 14 are brazed to the inner surface of a portion of the lower constituent member 8 of the casing 2, which portion forms the bottom wall 2b.

In the liquid-cooled-type cooling device 1 having the above-described structure, the cooling liquid having flowed from the inlet pipe 12 into the inlet header section 4 through the cooling liquid inlet 9 branches into the split flow channels 18 each formed between two adjacent fin plates 14 of the radiator 6 disposed in the cooling liquid flow channel 3, and flows leftward within each split flow channel 18. The cooling liquid having flowed leftward in the split flow channels 18 of the cooling liquid flow channel 3 enters the outlet header section 5, and is discharged from the outlet pipe 13 through the cooling liquid outlet 12.

The heat generated from the heat generation body P is radiated to the cooling liquid flowing through the split flow channels 18 of the cooling liquid flow channel 3, via the insulating member I, the top wall 2a of the casing 2, and the fin plates 14 of the radiator 6, whereby the heat generation body P is cooled.

Next, a method of manufacturing the radiator 6 will be described with reference to FIGS. 4 through 8.

First, press working is performed on an aluminum material plate 20 uncoiled from a coiled material so as to punch out a plurality of elongated rectangular fin plates 14 in a half-punched state such that the longitudinal direction of the fin plates 14 coincides with the width direction of the material plate 20, the width direction of the fin plates 14 coincides with the longitudinal direction of the material plate 20, and the opposite longitudinal ends of the fin plates 14 are connected through connection portions 21 to bridge portions 22 at opposite side edges of the material plate 20 located on opposite sides in the width direction thereof (first step). Each fin plate 14 has cutouts 16 and 17 which are formed in the opposite side edge portions of the fin plate 14 (located on opposite sides in the width direction thereof) at positions near the opposite ends in the longitudinal direction thereof.

In the first step, a portion of each fin plate 14, which portion extends between the cutouts 16 and 17 formed at positions near the opposite ends thereof, is deformed such that its cross sectional shape taken along a plane orthogonal to the width direction of the fin plate 14 becomes a wavy shape, whereby crest portions and trough portions are formed alternatingly.

Next, portions of the bridge portions 22 each located between adjacent fin plates 14 are bent into a generally S-like shape so that the width directions of the all the fin plates 14 coincide with the vertical direction (second step). The S-shaped bent portions of the bridge portions 22 are denoted by 23. Notably, the first step and the second step are continuously shown in FIG. 4, and a portion of FIG. 4 is shown in FIG. 5 on an enlarged scale.

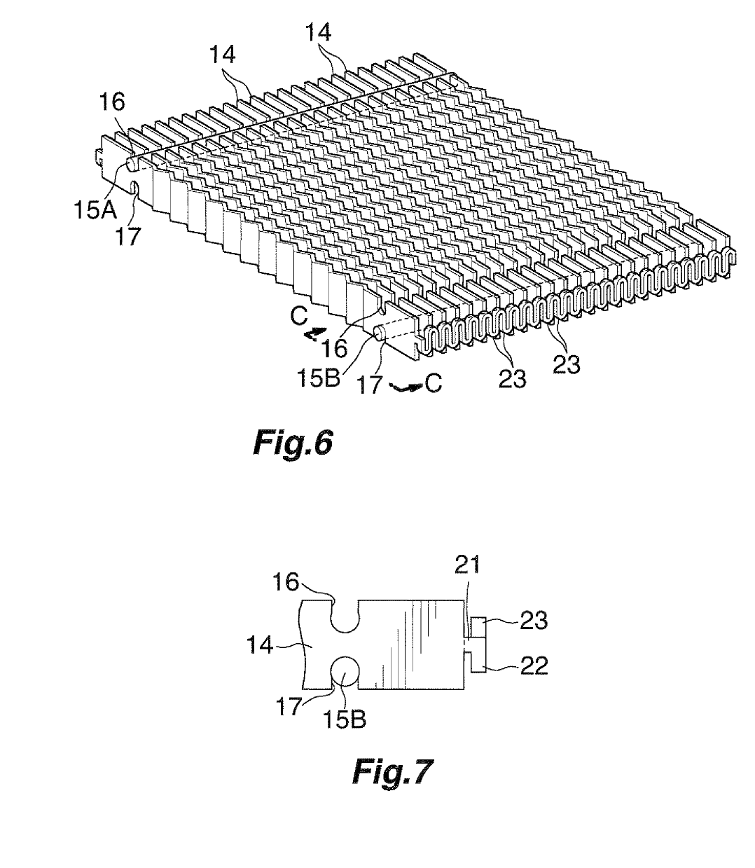

After the width directions of all the fin plates 14 are brought into coincidence with the vertical direction, the connection members 15A and 15B are respectively press-fitted into the first cutouts 16 formed in the left-end-side portions of the upper side edge portions of all the fin plates 14 and the second cutouts 17 formed in the right-end-side portions of the lower side edge portions of all the fin plates 14. Thus, all the fin plates 14 are connected and united together by the connection members 15A and 15B at positions on the diagonal lines of the fin plates 14 (third step) (see FIGS. 6 and 7).

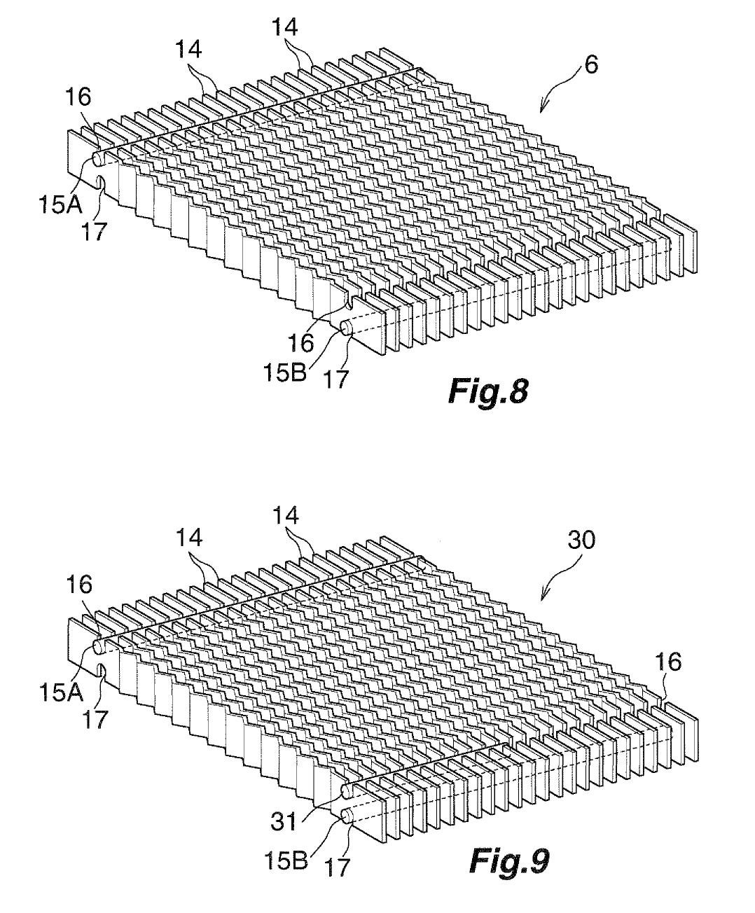

After that, all the connection portions 21 are cut, whereby all the fin plates 14 are separated from the bridge portions 22. In this manner, the radiator 6 is manufactured (fourth step) (see FIG. 8).

FIG. 9 shows another embodiment of the radiator for a liquid-cooled-type cooling device according to the present invention.

In the case of a radiator 30 shown in FIG. 9, a rod-shaped resistance imparting member 31 is disposed at a position near one end of each fin plate 14 in the longitudinal direction thereof such that the resistance imparting member 31 extends through only some of all the fin plates 14; i.e., a plurality of fin plates 14 located on one side in the direction of arrangement of the fin plates 14. The resistance imparting member 31 is press-fitted into third cutouts 16 formed in side edge portions (upper side edge portions in the illustrated example) of the fin plates 14 which are opposite the side edge portions (lower side edge portions) in which the second cutouts 17 are formed at a position near the above-mentioned one end so as to receive the second connection member 15B press-fitted thereinto.

The structure of the remaining portion is identical with that of the radiator 6 shown in FIG. 8.

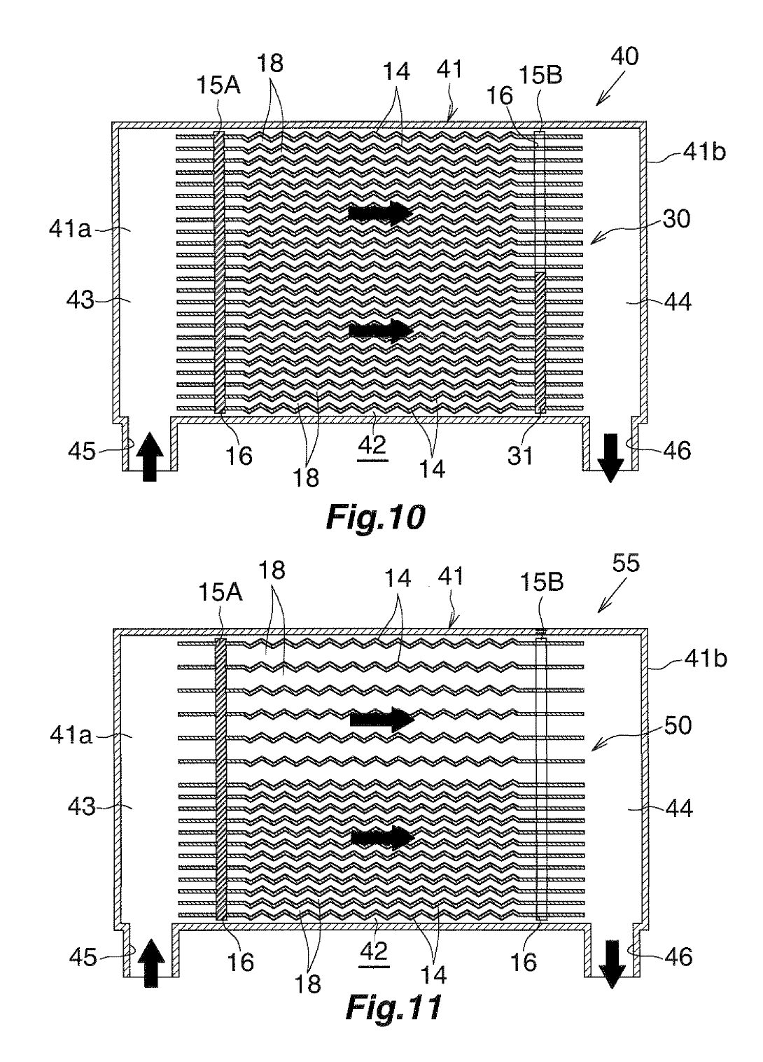

FIG. 10 shows a liquid-cooled-type cooling device in which the radiator 30 of FIG. 9 is used.

In the following description regarding FIG. 10, the left-hand and right-hand sides of the drawing will be referred to as “left” and “right,” respectively, the lower side of the drawing will be referred to as “front,” and the opposite side will be referred to as “rear.”

A liquid-cooled-type cooling device 40 shown in FIG. 10 includes a casing 41 having a top wall, a bottom wall 41a, and a peripheral wall 41b. Within the casing 41, there are provided a cooling liquid flow channel 42 through which a cooling liquid flows from one side (left-hand side) to the other side (right-hand side) of the casing 41 in the longitudinal direction thereof, an inlet header section 43 which is located upstream (leftward) of the cooling liquid flow channel 42 and into which the cooling liquid flows, and an outlet header section 44 which is located downstream (rightward) of the cooling liquid flow channel 42 and from which the cooling liquid flows out. The radiator 30 is disposed in the cooling liquid flow channel 42 within the casing 41.

The inlet header section 43 and the outlet header section 44 within the casing 41 are elongated in the width direction of the cooling liquid flow channel 42 (front-rear direction). A cooling liquid inlet 45 communicating with the inlet header section 43 is formed in a left end part of a front portion of the peripheral wall 41b of the casing 41. A cooling liquid outlet 46 communicating with the outlet header section 44 is formed in a right end part of the front portion of the peripheral wall 41b of the casing 41.

The radiator 30 is disposed in the cooling liquid flow channel 42 within the casing 41 such that the longitudinal direction of the fin plates 14 coincides with the flow direction (left-right direction) of the cooling liquid in the cooling liquid flow channel 42, the width direction of the fin plates 14 coincides with the vertical direction, and the resistance imparting member 31 is located on the side where the cooling liquid inlet 45 and the cooling liquid outlet 46 are provided. The upper side edge portions of all the fin plates 14 are brazed to the inner surface of the top wall of the casing 41, and the lower side edge portions of all the fin plates 14 are brazed to the inner surface of the bottom wall 41a of the casing 41.

In the liquid-cooled-type cooling device 40 shown in FIG. 10, the cooling liquid having flowed from the cooling liquid inlet 45 into the inlet header section 43 branches into the split flow channels 18 each formed between two adjacent fin plates 14 of the radiator 30 disposed in the cooling liquid flow channel 42, and flows rightward within each split flow channel 18. The cooling liquid having flowed rightward in the split flow channels 18 of the cooling liquid flow channel 42 enters the outlet header section 44, and is discharged through the cooling liquid outlet 46.

In the liquid-cooled-type cooling device 40 having the above-described structure, since the cooling liquid inlet 45 and the cooling liquid outlet 46 are provided at the ends of the inlet header section 43 and the outlet header section 44, which ends are located on the same side, the cooling liquid having flowed from the cooling liquid inlet 45 into the inlet header section 43 tends to flow through a region of the cooling liquid flow channel 42 on the side (front side) where the cooling liquid inlet 45 and the cooling liquid outlet 46 are provided.

However, since the resistance imparting member 31 is present on the front side where the cooling liquid inlet 45 and the cooling liquid outlet 46 are provided, it becomes difficult for the cooling liquid having flowed into the inlet header section 43 to flow through a region of the cooling liquid flow channel 42 on the side where the resistance imparting member 31 is disposed, and it becomes easy for the cooling liquid to flow through a region of the cooling liquid flow channel 42 on the opposite side. Accordingly, the distribution of flow rate in the direction of arrangement of the fin plates 14 in the radiator 30 can be made uniform, whereby a variation of cooling performance which is caused by a non-uniform distribution of flow rate can be restrained.

The heat generated from the heat generation body P is radiated to the cooling liquid flowing through the split flow channels 18 of the cooling liquid flow channel 42, via the insulating member I, the top wall of the casing 41, and the fin plates 14 of the radiator 30, whereby the heat generation body P is cooled.

FIG. 11 shows still another embodiment of the radiator for a liquid-cooled-type cooling device according to the present invention and a liquid-cooled-type cooling device in which that radiator is used.

In the following description regarding FIG. 11, the left-hand and right-hand sides of the drawing will be referred to as “left” and “right,” respectively, the lower side of the drawing will be referred to as “front,” and the opposite side will be referred to as “rear.”

In the case of a radiator 50 shown in FIG. 11, an inter-plate spacing which is the spacing between adjacent fin plates 14 gradually increases from one end side toward the other end side in the direction of arrangement of the fin plates 14. The structure of the remaining portion is identical with that of the radiator 6 shown in FIG. 8.

A liquid-cooled-type cooling device 55 using the radiator 50 has a casing 41 having the same structure as that of the casing of the liquid-cooled-type cooling device 40 shown in FIG. 10.

The radiator 50 is disposed such that the longitudinal direction of the fin plates 14 coincides with the flow direction (left-right direction) of the cooling liquid in the cooling liquid flow channel 42, the width direction of the fin plates 14 coincides with the vertical direction, and the side where the spacing between adjacent fin plates 14 is narrow is located on the side where the cooling liquid inlet 45 and the cooling liquid outlet 46 are provided. The upper side edge portions of all the fin plates 14 are brazed to the inner surface of the top wall of the casing 41, and the lower side edge portions of all the fin plates 14 are brazed to the inner surface of the bottom wall 41a of the casing 41.

In the liquid-cooled-type cooling device 55 shown in FIG. 11, the cooling liquid having flowed from the cooling liquid inlet 45 into the inlet header section 43 branches into the split flow channels 18 each formed between two adjacent fin plates 14 of the radiator 50 disposed in the cooling liquid flow channel 42, and flows rightward within each split flow channel 18. The cooling liquid having flowed rightward in the split flow channels 18 of the cooling liquid flow channel 42 enters the outlet header section 44, and is discharged through the cooling liquid outlet 46.

In the liquid-cooled-type cooling device 55 having the above-described structure, since the cooling liquid inlet 45 and the cooling liquid outlet 46 are provided at the ends of the inlet header section 43 and the outlet header section 44, which ends are located on the same side, the cooling liquid having flowed from the cooling liquid inlet 45 into the inlet header section 43 tends to flow through a region of the cooling liquid flow channel 42 on the side (front side) where the cooling liquid inlet 45 and the cooling liquid outlet 46 are provided.

However, since the radiator 50 is disposed such that the side where the spacing between adjacent fin plates 14 is narrow is located on the side where the cooling liquid inlet 45 and the cooling liquid outlet 46 are provided, it becomes difficult for the cooling liquid having flowed into the inlet header section 43 to flow through a region of the cooling liquid flow channel 42 on the side where the spacing between adjacent fin plates 14 of the radiator 50 is narrow, and it becomes easy for the cooling liquid to flow through a region of the cooling liquid flow channel 42 on the opposite side. Accordingly, the distribution of flow rate in the direction of arrangement of the fin plates 14 in the radiator 50 can be made uniform, whereby a variation of cooling performance which is caused by a non-uniform distribution of flow rate can be restrained.

The heat generated from the heat generation body P is radiated to the cooling liquid flowing through the split flow channels 18 of the cooling liquid flow channel 42, via the insulating member I, the top wall of the casing 41, and the fin plates 14 of the radiator 50, whereby the heat generation body P is cooled.

The liquid-cooled-type cooling device of the present invention is preferably used for cooling a power device, such as an IGBT, used in a power conversion apparatus mounted on an electric vehicle, a hybrid vehicle, an electric rail car, or the like.

What is claimed is:

1. A radiator for a liquid-cooled-type cooling device which includes a casing having a top wall, a bottom wall, and a peripheral wall, the cooling device having a cooling liquid flow channel which is provided in the casing and through which a cooling liquid having flowed into the casing flows, the cooling device being adapted to cool a heat generation body attached to at least one of an outer surface of the top wall of the casing and an outer surface of the bottom wall thereof by the cooling liquid flowing through the cooling liquid flow channel, the radiator being disposed in the cooling liquid flow channel within the casing and radiating heat generated from the heat generation body to the cooling liquid, the radiator comprising:
a plurality of elongated rectangular fin plates disposed in parallel such that the fin plates are spaced from one another; and
rod-shaped first and second connection members which extend in a direction intersecting with a longitudinal direction of the fin plates and which connect and unite all the fin plates together, wherein
all the fin plates are disposed, while being spaced from one another in a thickness direction of the fin plates, such that the longitudinal direction of the fin plates coincides with a flow direction of the cooling liquid, and a width direction of the fin plates coincides with a vertical direction;
the first connection member is fixed to one of side edge portions of each fin plate located on opposite sides in the width direction, and the second connection member is fixed to the other of the side edge portions of the fin plate;
a first cutout into which the first connection member is press-fitted is formed in the one side edge portion of each fin plate, and a second cutout into which the second connection member is press-fitted is formed in the other side edge portion of the fin plate at a position shifted from the first cutout in the longitudinal direction of the fin plate; and
the first connection member is press-fitted into the first cutout such that the first connection member does not project from the first cutout, and the second connection member is press-fitted into the second cutout such that the second connection member does not project from the second cutout, whereby all the fin plates are connected and united together by the first and second connection members.

2. A radiator for a liquid-cooled-type cooling device according to claim 1, wherein each fin plate has a wavy sectional shape when the fin plate is cut along a plane orthogonal to the width direction thereof and has crest portions and trough portions formed alternatingly, and the cooling liquid flows between two adjacent fin plates while meandering.

3. A radiator for a liquid-cooled-type cooling device according to claim 1, wherein the first cutout is formed in the one side edge portion of each fin plate at a position near a first end in the longitudinal direction, the second cutout is formed in the other side edge portion of the fin plate at a position near a second end in the longitudinal direction, a third cutout is formed in the one side edge portion of the fin plate at a position near the second end in the longitudinal direction, and a fourth cutout is formed in the other side edge portion of the fin plate at a position near the first end in the longitudinal direction.

4. A radiator for a liquid-cooled-type cooling device according to claim 3, wherein
an inter-plate spacing which is a spacing between adjacent fin plates is the same among all the fin plates;
a rod-shaped resistance imparting member is disposed at a position near the second ends of the fin plates in the longitudinal direction such that the resistance imparting member extends through a plurality of fin plates which are a portion of all the fin plates and are located on one side in a direction of arrangement of the fin plates; and
the resistance imparting member is fitted into the third cutout of each fin plate which is formed in the one side edge portion thereof at a position near the second end.

5. A radiator for a liquid-cooled-type cooling device according to claim 1, wherein an inter-plate spacing which is a spacing between adjacent fin plates is narrow on one side in a direction of arrangement of the fin plates, and is wide on the other side in the direction of arrangement.

6. A radiator for a liquid-cooled-type cooling device according to claim 5, wherein the inter-plate spacing which is the spacing between adjacent fin plates gradually increases from one side toward the other side in the direction of arrangement of the fin plates.

7. A liquid-cooled-type cooling device comprising:
a casing having a top wall, a bottom wall, and a peripheral wall;
a cooling liquid flow channel which is provided in the casing and through which a cooling liquid flows;
an inlet header section which is provided in the casing to be located upstream of the cooling liquid flow channel and into which the cooling liquid flows;
an outlet header section which is provided in the casing to be located downstream of the cooling liquid flow channel and from which the cooling liquid flows out; and
a radiator which is disposed in the cooling liquid flow channel within the casing and which radiates heat to the cooling liquid flowing through the cooling liquid flow channel, the heat being generated from a heat generation body attached to at least one of an outer surface of the top wall of the casing and an outer surface of the bottom wall of the casing, wherein
the radiator for a liquid-cooled-type cooling device according to claim 1 is disposed such that the longitudinal direction of the fin plates coincides with a direction along which the inlet header section and the outlet header section are provided and the width direction of the fin plates coincides with the vertical direction; and
upper side edge portions of all the fin plates are joined to the top wall of the casing, and lower side edge portions of all the fin plates are joined to the bottom wall of the casing.

8. A liquid-cooled-type cooling device according to claim 7, wherein each fin plate of the radiator has a wavy sectional shape when the fin plate is cut along a plane orthogonal to the width direction thereof and has crest portions and trough portions formed alternatingly, and the cooling liquid flows between two adjacent fin plates while meandering.

9. A liquid-cooled-type cooling device according to claim 7, wherein the first cutout is formed in the one side edge portion of each fin plate of the radiator at a position near a first end in the longitudinal direction, the second cutout is formed in the other side edge portion of the fin plate at a position near a second end in the longitudinal direction, a third cutout is formed in the one side edge portion of the fin plate at a position near the second end in the longitudinal direction, and a fourth cutout is formed in the other side edge portion of the fin plate at a position near the first end in the longitudinal direction.

10. A liquid-cooled-type cooling device according to claim 9, wherein
the inlet header section and the outlet header section of the casing are elongated in a direction orthogonal to a flow direction of the cooling liquid in the cooling liquid flow channel,
a cooling liquid inlet is provided at one end of the inlet header section, and a cooling liquid outlet is provided at one end of the outlet header section which is located on the same side as the one end of the inlet header section;
an inter-plate spacing which is a spacing between adjacent fin plates of the radiator is the same among all the fin plates;
a rod-shaped resistance imparting member is disposed at a position near the second ends of the fin plates in the longitudinal direction such that the resistance imparting member extends through a plurality of fin plates which are a portion of all the fin plates and are located on one side in a direction of arrangement of the fin plates;
the resistance imparting member is fitted into the third cutout of each fin plate which is formed in the one side edge portion thereof at a position near the second end; and
the radiator is disposed such that the side of the radiator where the resistance imparting member is located on the side where the cooling liquid inlet and the cooling liquid outlet are provided.

11. A liquid-cooled-type cooling device according to claim 7, wherein
the inlet header section and the outlet header section of the radiator are elongated in a direction orthogonal to a flow direction of the cooling liquid in the cooling liquid flow channel,
a cooling liquid inlet is provided at one end of the inlet header section, and a cooling liquid outlet is provided at one end of the outlet header section which is located on the same side as the one end of the inlet header section;
an inter-plate spacing which is a spacing between adjacent fin plates of the radiator is narrow on one side in a direction of arrangement of the fin plates, and is wide on the other side in the direction of arrangement; and
the radiator is disposed such that the side of the radiator where the inter-plate spacing is narrow is located on the side where the cooling liquid inlet and the cooling liquid outlet are provided.

12. A liquid-cooled-type cooling device according to claim 7, wherein
the inlet header section and the outlet header section are elongated in a direction orthogonal to a flow direction of the cooling liquid in the cooling liquid flow channel,
a cooling liquid inlet is provided at one end of the inlet header section, and a cooling liquid outlet is provided at one end of the outlet header section which is located on the same side as the one end of the inlet header section;
an inter-plate spacing which is a spacing between adjacent fin plates of the radiator gradually increases from one side toward the other side in a direction of arrangement of the fin plates; and
the radiator is disposed such that the side of the radiator where the inter-plate spacing is narrow is located on the side where the cooling liquid inlet and the cooling liquid outlet are provided.

13. A method of manufacturing a radiator for a liquid-cooled-type cooling device which includes a casing having a top wall, a bottom wall, and a peripheral wall, the cooling device having a cooling liquid flow channel which is provided in the casing and through which a cooling liquid having flowed into the casing flows, the cooling device being adapted to cool a heat generation body attached to at least one of an outer surface of the top wall of the casing and an outer surface of the bottom wall thereof by the cooling liquid flowing through the cooling liquid flow channel, the radiator being disposed in the cooling liquid flow channel within the casing and radiating heat generated from the heat generation body into the cooling liquid, the radiator including a plurality of elongated rectangular fin plates disposed in parallel such that the fin plates are spaced from one another, and rod-shaped first and second connection members which extend in a direction intersecting with a longitudinal direction of the fin plates and which connect and unite all the fin plates together, wherein all the fin plates are disposed, while being spaced from one another in a thickness direction of the fin plates, such that the longitudinal direction of the fin plates coincides with a flow direction of the cooling liquid, and a width direction of the fin plates coincides with a vertical direction, the first connection member is fixed to one of side edge portions of each fin plate located on opposite sides in the width direction, and the second connection member is fixed to the other of the side edge portions of the fin plate, a first cutout into which the first connection member is press-fitted is formed on the one side edge portion of each fin plate at a position near a first end in the longitudinal direction of the fin plate, and a second cutout into which the second connection member is press-fitted is formed on the other side edge portion of the fin plate at a position near a second end in the longitudinal direction of the fin plate, and the first connection member is press-fitted into the first cutout such that the first connection member does not project from the first cutout, and the second connection member is press-fitted into the second cutout such that the second connection member does not project from the second cutout, whereby all the fin plates are connected and united together by the first and second connection members,
the method comprising:
a first step of performing press working on a metal material plate so as to punch out a plurality of elongated rectangular fin plates in a half-punched state such that a longitudinal direction of the fin plates coincides with a width direction of the metal material plate, a width direction of the fin plates coincides with a longitudinal direction of the metal material plate, and opposite longitudinal ends of the fin plates are connected to respective bridge portions through connection portions, each fin plate having the first cutout which is formed in one side edge portion of the fin plate located on one side in the width direction thereof to be located at a position near the first end in the longitudinal direction, the second cutout which is formed in the other side edge portion of the fin plate located on the other side in the width direction thereof to be located at a position near the second end in the longitudinal direction;
a second step of bending parts of the bridge portions, each part being located between adjacent fin plates, into a generally S-like shape, to thereby bring the width direction of all the fin plates into coincident with the vertical direction;
a third step of press-fitting the first connection member into the first cutouts of all the fin plates such that the first connection member does not project from the first cutouts and press-fitting the second connection member into the second cutouts of all the fin plates such that the second connection member does not project from the second cutouts; and
a fourth step of cutting all the connection portions which connect the fin plates to the bridge portions to thereby separate all the fin plates from the bridge portions.

14. A method of manufacturing a radiator for a liquid-cooled-type cooling device according to claim 13, wherein, in the first step, a portion of each fin plate between the first and second cutouts is deformed to have a wavy sectional shape when the fin plate is cut along a plane orthogonal to the width direction thereof.

15. A method of manufacturing a radiator for a liquid-cooled-type cooling device according to claim 13, wherein, in the first step, a third cutout is formed in the one side edge portion of the fin plate at a position near the second end in the longitudinal direction, and a fourth cutout is formed in the other side edge portion of the fin plate at a position near the first end in the longitudinal direction.
